(19) United States
(12) Patent Application Publication
(10) Pub. No.: US 2010/0020478 A1
(43) Pub. Date: Jan. 28, 2010

(54) ELECTRONIC APPARATUS AND MOTHERBOARD THEREOF

(75) Inventor: Chun-Yan Yan Chu, Taipei (TW)

Correspondence Address: MORRIS MANNING MARTIN LLP, 3343 PEACHTREE ROAD, NE, 1600 ATLANTA FINANCIAL CENTER, ATLANTA, GA, 30326, US

(73) Assignee: ASUSTek Computer Inc., Taipei (TW)

(21) Appl. No.: 12/485,548

(22) Filed: Jun. 16, 2009

(30) Foreign Application Priority Data
Jul. 23, 2008 (TW) 097127989

(51) Int. Cl. H05K 7/00; H05K 1/00

(52) U.S. Cl. 361/679.02; 361/748

(57) ABSTRACT

The invention discloses a motherboard applied to an electronic apparatus. The motherboard has a first surface and a second surface opposite to the first surface. The motherboard comprises a decorative pattern, a socket, one or more slots, and a plurality of first electronic components. The decorative pattern is formed on the first surface. The socket and the slot(s) are disposed on the first surface, wherein the socket is used for disposing a second electronic component, such as a central processing unit. The first electronic components are disposed on the second surface, wherein the first electronic components comprise resistor, inductor, capacitor, integrated circuit, or Metal-Oxide-Semiconductor (MOS).

### BACKGROUND OF THE INVENTION

1. Field of the Invention

This invention relates to a motherboard, and more particularly to an electronic apparatus and the motherboard thereof.

2. Description of the Related Art

Among computer components, the motherboard plays the role of “platform” and connects other components to become an integer. The [so-called NOTE: Why did you use this word? This means supposed.] CPU (Central Processing Unit) is like a brain which is responsible for all calculation tasks, and the motherboard is like a spine. The motherboard connects peripherals such as an expansion card, a hard disk, the network, a speaker, a keyboard, a mouse, and the printer for the CPU to control.

Please refer to FIG. 1. FIG. 1 is a schematic diagram illustrating a motherboard 1 in prior arts. Even though the motherboard is not the most advanced component, it is the component which has the most parts or other components. Generally, some basic electronic components are disposed on every motherboard. As shown in FIG. 1, the known motherboard 1 includes a socket 10, slots 11, a north bridge 12, a south bridge 13, expansion card slots 14, hard disk/CD-ROM drive slots 15, integrated peripherals 16, a BIOS (Basic Input/Output System) 17, and a power connector 18.

The socket 10 is used for disposing a CPU (not shown). The CPU is a precise electronic component which has a working voltage in a constant range. If the work voltage is too high or too low, the CPU will be damaged. Therefore, a lot of capacitors 20 and inductors 22 will be arranged around the socket 10 to regulate the voltage. The slots 11 are used for memory (not shown). A motherboard usually has two, four, or more slots which are adjacent to the socket 10 and the north bridge 12.

The north bridge 12, which is responsible for connecting the CPU, memory, and video card, is the most important chip on the motherboard 1. CPU's generate a lot of heat; therefore motherboards of a higher class are usually assembled with heat dissipating fins or fans. The south bridge 13 and the north bridge 12 are connected to each other and connect to other peripherals. Well known functions of the motherboard 1 are performed by the south bridge 13. For example, the USB (Universal Serial Bus), network, audio, and SATA/IDE hard disk are connected from the south bridge 13.

Presently, although some motherboards are embedded with all the necessary components, such as a network, audio, even a video card, expansion needs are still necessary. The expansion card slots 14 are used for inserting cards, such as a TV card or a wireless card, etc. Commonly, an expansion slot is usually used by a video card.

Furthermore, the hard disk/CD-ROM drive slots 15 include a SATA slot (not shown) and an IDE slot (not shown). The IDE slot is used to connect a CD-ROM drive, and the connection interfaces of hard disks have almost entirely been changed to SATA. The integrated peripherals 16 include input/output interfaces of various function kinds of the motherboard 1, such as a USB and a network socket, an audio input/output socket, a keyboard or a mouse with PS/2 interface, etc.

The BIOS 17, like the embedded “software” of the motherboard 1, is used for recognizing all devices on the motherboard 1 and adjusting all settings and then be booted by the OS. The software of the BIOS is usually stored in a small flash ROM.

Moreover, all of the north bridge 12, the south bridge 13, the memory, the video card, and the USB need power, and the power is supplied to the motherboard 1 by the power connector 18. The power connector 18 is used for plugging in a power supply. Like other power inputting locations of the motherboard 1, a lot of capacitors are disposed near the power connector 18.

Besides the forgoing major electronic components, electronic components such as resistors, Integrated Circuits (IC), and Metal-Oxide-Semiconductors (MOS) are arranged on the motherboard 1 such that the surface of the motherboard 1 seems crowded. It is easy to interfere with other electronic components and makes it more difficult to install other components when a user wants to connect a CPU, memory, a video card, or other row lines to the motherboard 1.

Besides, more and more computer housings are designed to be transparent nowadays, so that users can watch the motherboards which are disposed in the housings directly. Because electronic components are fully disposed on the motherboard 1, it looks disorderly and will influence visual effects in usage.

### SUMMARY OF THE INVENTION

A scope of the invention is to provide a motherboard which is disposed in an electronic apparatus. Major components and slots are disposed on the front side of the motherboard, and a lot of secondary components are disposed on the rear side of the motherboard, so that much space will be left on the front side of the motherboard.

According to an embodiment, the motherboard of the invention has a first surface (i.e., the front side) and a second surface (i.e. the rear side) opposite to the first surface. The motherboard includes a decorative pattern, a socket, one or more slots, and a plurality of first electronic components.

In the embodiment, the decorative pattern is formed on the first surface, wherein the decorative pattern can be images, letters, or the combination thereof. The socket and the slots are disposed on the first surface, wherein the socket is used for disposing a second electronic component, such as a CPU. The plurality of the first electronic components are disposed on the second surface, wherein the first electronic components include a resistor, an inductor, a capacitor, an integrated circuit, or a Metal-Oxide-Semiconductor (MOS).

As above, the secondary electronic components such as resistors, inductors, capacitors, ICs, and MOSs are moved to the second surface (i.e., the rear side), so the increased space on the first surface (i.e., the front side) will increase usability. Moreover, the first surface of the motherboard has the decorative pattern which can beautify the motherboard and increase the visual effect in usage. Furthermore, the electronic components which will generate noises are separated on the second surface, so as to increase the stability of signals. When wires and through holes on the first surface are decreased, the signals will not decay at the through holes.

The advantage and spirit of the invention may be understood by the following recitations together with the appended drawings.

### BRIEF DESCRIPTION OF THE APPENDED DRAWINGS

FIG. 1 is a schematic diagram illustrating a motherboard in prior arts.

FIG. 2A is a schematic diagram illustrating an electronic apparatus of an embodiment of the invention.

FIG. 2B is a schematic diagram illustrating the electronic apparatus whose side plate has been removed in FIG. 2A.

FIG. 3 is an enlarged view illustrating the motherboard in FIG. 2B.

FIG. 4 is a schematic diagram illustrating the rear side of the motherboard in FIG. 3.

### DETAILED DESCRIPTION OF THE INVENTION

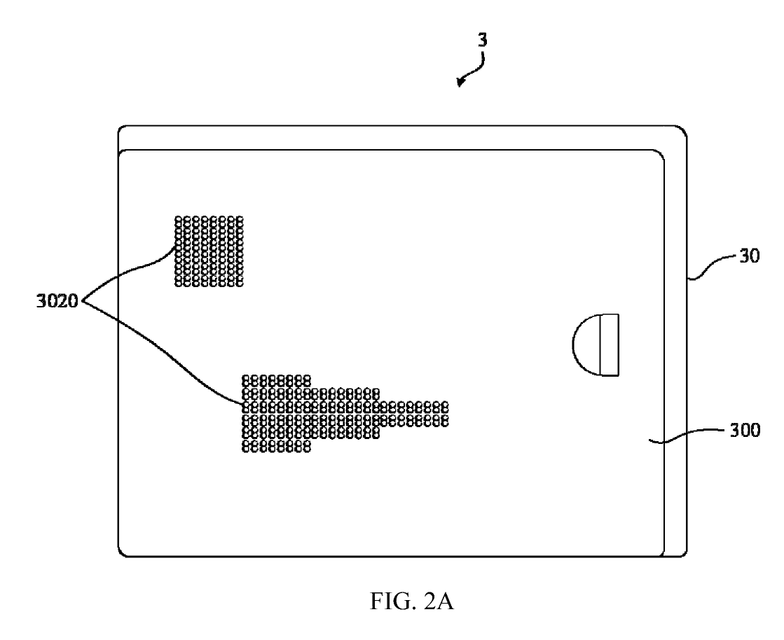

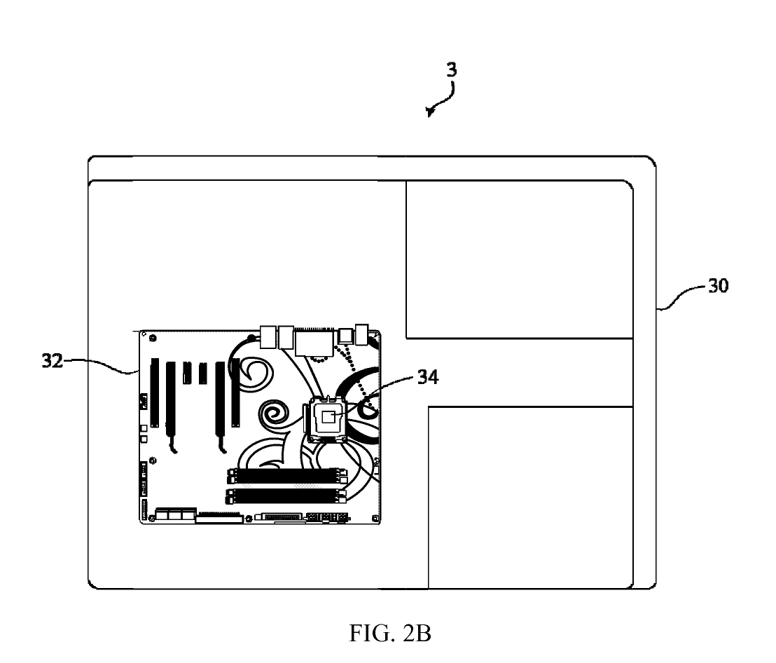

Please refer to FIG. 2A and FIG. 2B. FIG. 2A is a schematic diagram illustrating an electronic apparatus of an embodiment of the invention. FIG. 2B is a schematic diagram illustrating the electronic apparatus whose side plate has been removed in FIG. 2A. The electronic apparatus 3 in FIG. 2A and FIG. 2B takes a housing of a computer as an example. As shown in FIG. 2A and FIG. 2B, the electronic apparatus 3 includes a housing 30, a motherboard 32, and a second electronic component 34. In the embodiment, the second electronic component 34 is a CPU which is responsible for all calculation tasks. In general, except the motherboard 32 and the second electronic component 34, there are many electronic apparatuses (not shown) with different functions in the housing 30, such as a fan, a hard disk, a CD-ROM drive, a power supply, etc. The functions of the foregoing electronic apparatuses are well known and can be easily applied, so they will not be discussed detailed here.

In the embodiment, the housing 30 includes a removable side plate 300. When one of the foregoing electronic apparatuses malfunctions, a user can remove the side plate 300 to replace the electronic apparatus which is disposed in the housing 30. Moreover, in order to increase the effect of dissipating heat, the side plate 300 usually has a lot of apertures 3020. The airflow generated by a fan (not shown) can bring the heat generated in the housing 30 out of the housing 30 through the apertures 3020.

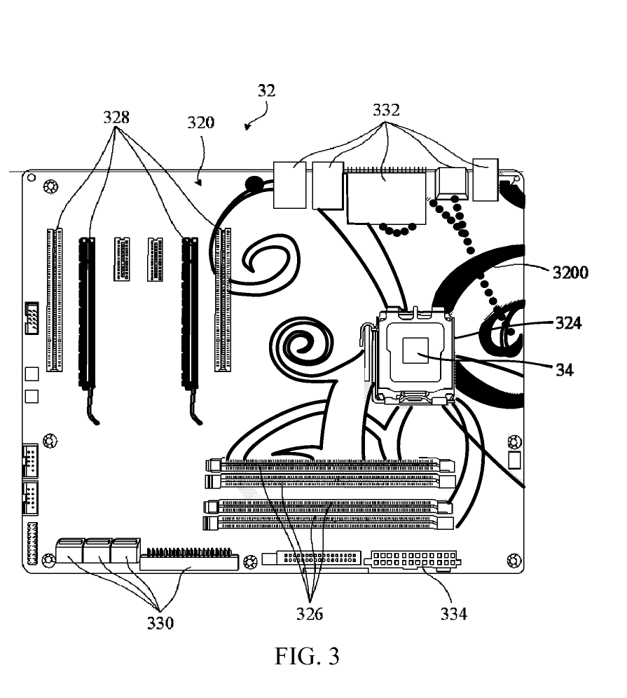

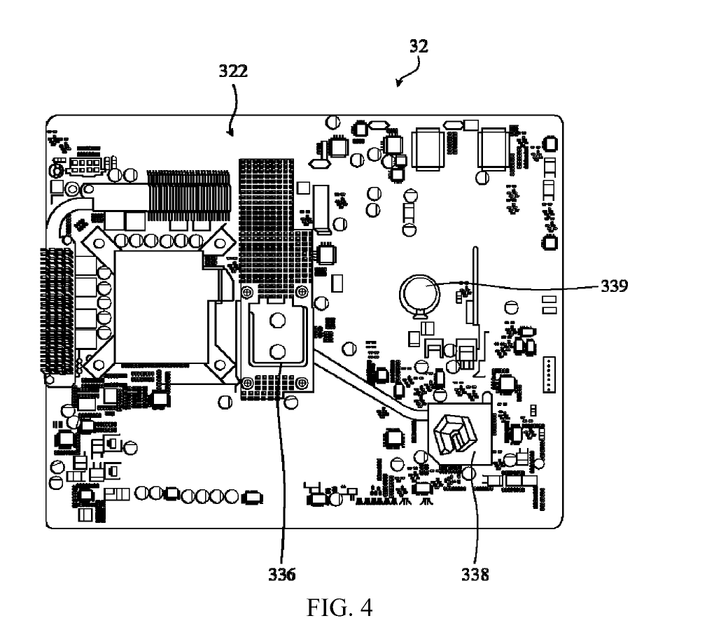

Please refer to FIG. 3 and FIG. 4. FIG. 3 is an enlarged view illustrating the motherboard 32 in FIG. 2B. FIG. 4 is a schematic diagram illustrating the rear side of the motherboard 32 in FIG. 3. The motherboard 32 has a surface 320 (i.e., the front side of the motherboard 32 in FIG. 3) and a surface 322 (i.e., the rear side of the motherboard 32 in FIG. 4) opposite to the surface 320. In the embodiment, the motherboard 32 includes a decorative pattern 3200 formed on the surface 320, a socket 324 disposed on the surface 320, and a plurality of slots. The slots include memory slots 326, expansion card slots 328, hard disk/CD-ROM drive slots 330, integrated peripherals 332, and a power connector 334. The foregoing slots are well known and can be easily applied, so they will not be discussed detailed here. It is needed to be explained that although the foregoing embodiment takes the plurality of slots as an example, the slots which are disposed on the motherboard 32 are unconstraint.

On the other hand, in the embodiment, a first electronic component is disposed on the surface 322 of the motherboard 32. The first electronic component can include a north bridge 336, a south bridge 338, a BIOS 339, or other secondary electronic components (such as a resistor, an inductor, a capacitor, an IC, or a MOS). The foregoing first electronic components are well known and can be easily applied, so they will not be discussed detailed here.

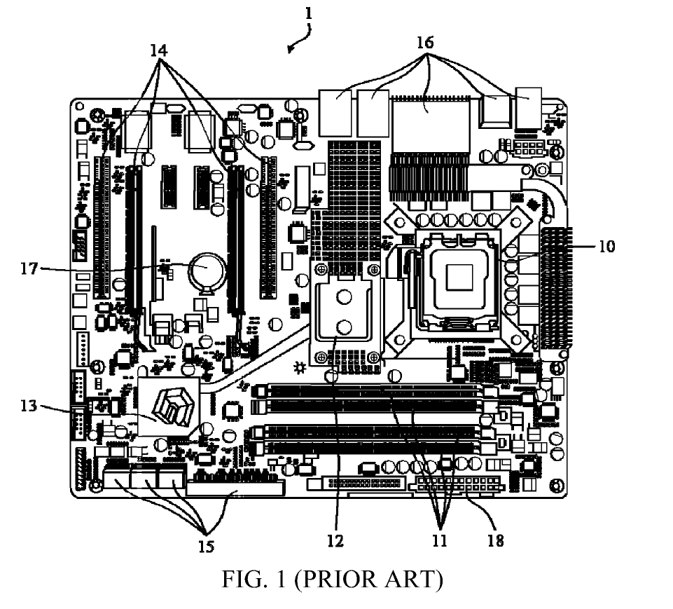

It can be known above that only the socket 324 and the foregoing slots are disposed on the surface 320 (i.e., the front side of the motherboard 32) of the motherboard 32 of the embodiment of the invention, and the first electronic components (such as the north bridge 336, the south bridge 338, the BIOS 339, and other secondary electronic components) are disposed on the surface 322 of the motherboard 32, so as to make the surface 320 of the motherboard 32 more ordered than the traditional motherboard 1 in FIG. 1. With the foregoing configurations and arrangements, much space can be left on the surface 320 of the motherboard 32 to increase usability. Of course, in other embodiments, the north bridge 336, the south bridge 338, and the BIOS 339 can also left on the surface 320 of the motherboard 32, and the first electronic components are limited to secondary electronic components (such as a resistor, an inductor, a capacitor, an IC, or a MOS). Whether the north bridge 336, the south bridge 338, and the BIOS 339 will be moved on the surface 322 of the motherboard 32 depends on practical applications and does not constrained in the invention.

In the embodiment, because only major electronic components are disposed on the surface 320 of the motherboard 32, and the secondary electronic components (such as a resistor, an IC, or a MOS) are disposed on the surface 322 (i.e., the rear side of the motherboard 32) of the motherboard 32, much space can be left on the surface 320 (i.e., the front side of the motherboard 32) of the motherboard 32. Therefore, it is uneasy to interfere with other electronic components and is ease of installing when a user wants to connect a CPU, memory, a video card, or other row lines to the motherboard 32.

The front side of the motherboard 32 has the decorative pattern 3200 which can beautify the motherboard and increase the visual effect in usage. Furthermore, when the side plate 300 in FIG. 2A is a transparent plate, a user can watch the decorative pattern 3200 on the surface 320 of the motherboard 32 directly, which make the visual effect of the electronic apparatus 3 much better. Wherein, the decorative pattern 3200 can be images, letters, or the combination thereof, but does not limited to the pattern in FIG. 3.

Furthermore, the embodiment will separate the electronic components which generate noises on the rear side of the motherboard 32, so as to increase the stability of signals. When wires and through holes on the front side of the motherboard 32 are decreased, the signals will not decay at the through holes.

With the example and explanations above, the features and spirits of the invention will be hopefully well described. Those skilled in the art will readily observe that numerous modifications and alterations of the device may be made while retaining the teaching of the invention. Accordingly, the above disclosure should be construed as being limited only by the metes and bounds of the appended claims.

What is claimed is:

1. A motherboard having a first surface and a second surface, the motherboard comprising:
a decorative pattern being formed on the first surface;
a socket being disposed on the first surface;
a slot being disposed on the first surface; and
a plurality of first electronic components being disposed on the second surface.

2. The motherboard of claim 1, wherein the decorative pattern comprises images, letters, or the combination thereof.

3. The motherboard of claim 1, wherein the socket is used for disposing a second electronic component.

4. The motherboard of claim 3, wherein the second electronic component is a central processing unit.

5. The motherboard of claim 1, wherein the first electronic components comprise resistor, inductor, capacitor, integrated circuit, or Metal-Oxide-Semiconductor (MOS).

6. An electronic apparatus comprising:
a housing;
a motherboard, disposed in the housing, having a first surface and a second surface opposite to the first surface, the motherboard comprising:
a decorative pattern being formed on the first surface;
a socket being disposed on the first surface;
a slot being disposed on the first surface; and
a plurality of first electronic components being disposed on the second surface; and
a second electronic component being disposed on the socket.

7. The electronic apparatus of claim 6, the decorative pattern comprises images, letters, or the combination thereof.

8. The electronic apparatus of claim 6, wherein the second electronic component is a central processing unit.

9. The electronic apparatus of claim 6, wherein the first electronic components comprise resistor, inductor, capacitor, integrated circuit, or Metal-Oxide-Semiconductor (MOS).
